(19) United States
(12) Patent Application Publication
(10) Pub. No.: US 2021/0098678 A1
(43) Pub. Date: Apr. 1, 2021

(54) FLEXIBLE THERMOELECTRIC DEVICE

(71) Applicant: 3M INNOVATIVE PROPERTIES COMPANY, St. Paul, MN (US)

(72) Inventors: Ravi Palaniswamy, Choa Chu Kang (SG); Antonny E. Flor, Sembawang (SG); HongQian Bao, Toa Payoh (SG); Jaime L. Angeles, Admiralty Link (SG); Jae Yong Lee, Santa Clara, CA (US); Mahmut Aksit, Woodbury, MN (US)

(21) Appl. No.: 15/733,294

(22) PCT Filed: Dec. 20, 2018
(86) PCT No.: PCT/IB2018/060477

§ 371 Date: Jun. 22, 2020

Related U.S. Application Data
(60) Provisional application No. 62/610,537, filed on Dec. 27, 2017.

(51) Int. Cl. H01L 35/32; H01L 35/30; A42B 3/28; H01L 35/24

(52) U.S. Cl. CPC H01L 35/32; H01L 35/30; A42B 3/288; H01L 35/24; A42B 3/286; A42B 3/285

(57) ABSTRACT

Flexible thermoelectric devices including a flexible heat management layer on the hot side thereof, and methods of making and using the same, are provided. The flexible heat management layer includes a water harvesting material configured to absorb water or moisture and dissipate heat by evaporation of the absorbed water or moisture. In some cases, the water harvesting material includes a mixture of a superabsorbent polymer (SAP) material and a metal-organic framework (MOF) material.

### TECHNICAL FIELD

The present disclosure relates to flexible thermoelectric devices including a flexible heat management layer on the hot side thereof, and methods of making and using the same.

### BACKGROUND

Thermoelectric devices have been widely used for heating or cooling. Heat sinks (e.g., ceramic or metal plates) are used for managing heat on the hot side of the thermoelectric device.

### SUMMARY

The present disclosure provides a flexible thermoelectric device including a flexible heat management layer on the hot side thereof, and methods of making and using the same.

In one aspect, the present disclosure describes a thermoelectric device including a flexible substrate having opposite first and second sides, and a plurality of thermoelectric elements supported by the flexible substrate. The plurality of thermoelectric elements are electrically connected by a first set of electrodes on the first side and a second set of electrodes on the second side. One or more water harvesting materials are disposed on the first side to absorb water or moisture and dissipate heat by evaporation.

In another aspect, the present disclosure describes a thermoelectric cooler (TEC). The TEC includes a thermoelectric device including a flexible substrate having opposite first and second sides, and a plurality of thermoelectric elements supported by the flexible substrate. The plurality of thermoelectric elements are electrically connected by a first set of electrodes on the first side and a second set of electrodes on the second side. One or more water harvesting materials are disposed on the first side to absorb water or moisture and dissipate heat by evaporation. The TEC further includes a flexible metal film disposed on the second side as a cold plate.

In another aspect, the present disclosure describes a protective helmet including a helmet body including an outer shell and an inner shell. A thermoelectric cooler (TEC) is disposed between the outer shell and the inner shell of the helmet body. The TEC includes a thermoelectric device including a flexible substrate having opposite first and second sides, and a plurality of thermoelectric elements supported by the flexible substrate. The plurality of thermoelectric elements are electrically connected by a first set of electrodes on the first side and a second set of electrodes on the second side. One or more water harvesting materials are disposed on the first side to absorb water or moisture and dissipate heat by evaporation. The TEC further includes a flexible metal film disposed on the second side as a cold plate. The cold plate being adjacent to the inner shell.

In another aspect, the present disclosure describes an air respirator system including a head gear, an air box including an air inlet and an air outlet, a breathing tube fluidly connected air outlet of the air box to the head gear, and a thermoelectric cooler (TEC) positioned to cool an air flow into the head gear. The TEC includes a thermoelectric device including a flexible substrate having opposite first and second sides, and a plurality of thermoelectric elements supported by the flexible substrate. The plurality of thermoelectric elements are electrically connected by a first set of electrodes on the first side and a second set of electrodes on the second side. One or more water harvesting materials are disposed on the first side to absorb water or moisture and dissipate heat by evaporation. The TEC further includes a flexible metal film disposed on the second side as a cold plate. The cold plate is positioned adjacent to the inner shell.

In another aspect, the present disclosure describes a method of making a thermoelectric device. The method includes providing a flexible substrate having opposite first and second sides, and providing a plurality of thermoelectric elements supported by the flexible substrate. The plurality of thermoelectric elements are electrically connected by a first set of electrodes on the first side and a second set of electrodes on the second side. The method further includes disposing one or more water harvesting materials on the first side configured to absorb water or moisture and dissipate heat by evaporation of the absorbed water or moisture.

Various unexpected results and advantages are obtained in exemplary embodiments of the disclosure. One such advantage of exemplary embodiments of the present disclosure is that it eliminates the necessity of using rigid heatsinks (e.g., metal blocks) to dissipate heat on the hot side of a flexible thermoelectric device. Instead, a flexible heat management layer is applied onto the hot side of a flexible thermoelectric circuitry, which results in a flexible thermoelectric device (e.g., a thermoelectric cooler) that is cost-effective, volume-efficient, and easy to operate.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A illustrates a schematic cross-sectional view of a flexible thermoelectric device, according to one embodiment.

FIG. 1B illustrates a schematic cross-sectional view of the flexible thermoelectric device of FIG. 1A including a layer of thermal interface material (TIM), according to one embodiment.

FIG. 1C illustrates a schematic cross-sectional view of the flexible thermoelectric device of FIG. 1B including a superabsorbent polymer (SAP) material disposed on the TIM, according to one embodiment.

FIG. 1D illustrates a schematic cross-sectional view of the flexible thermoelectric device of FIG. 1B including a metal-organic framework (MOF) material disposed on the TIM, according to one embodiment.

FIG. 2A illustrates a simplified schematic perspective view of a protective helmet including a thermoelectric cooler, according to one embodiment.

FIG. 2B illustrates a cross-sectional view of a portion of the protective helmet of FIG. 2A.

FIG. 2C illustrates a perspective view of a portion of the protective helmet of FIG. 2A.

FIG. 3A illustrates a schematic view of an air respirator system including a thermoelectric cooler disposed in an air box, according to one embodiment.

FIG. 3B illustrates a schematic view of an air respirator system including a thermoelectric cooler disposed inside a breathing tube, according to another embodiment.

FIG. 3C illustrates a cross-sectional view of the breathing tube of FIG. 3B.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

The present disclosure provides a flexible thermoelectric device including one or more water harvesting materials disposed on a hot side of the device, configured to absorb water or moisture and dissipate heat by evaporation of the absorbed water or moisture. In some embodiments, the flexible thermoelectric device can work as a thermoelectric cooler (TEC) used for various applications such as a protective helmet and an air respirator system.

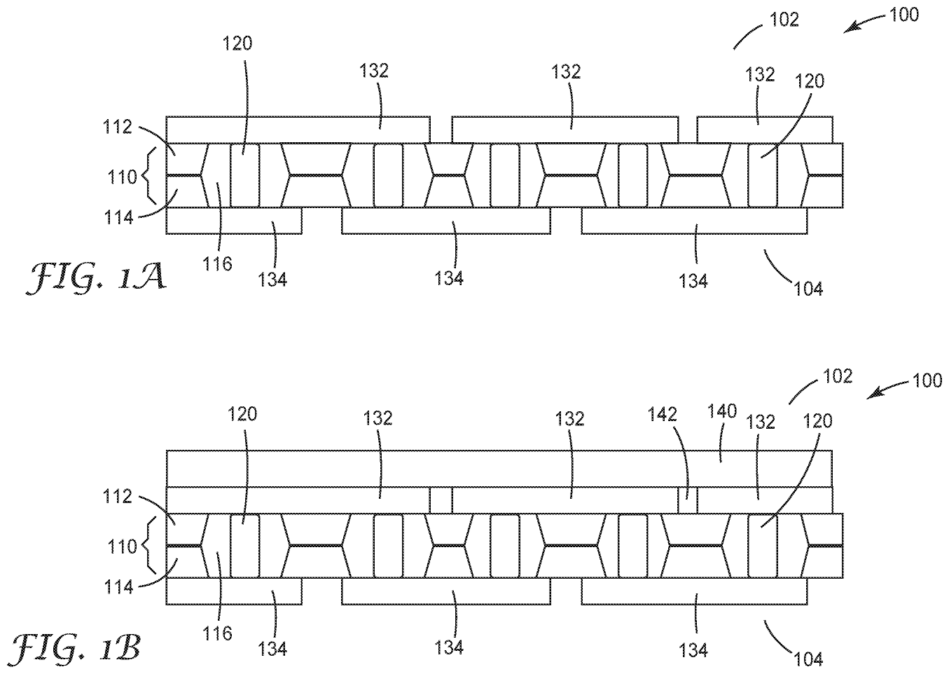

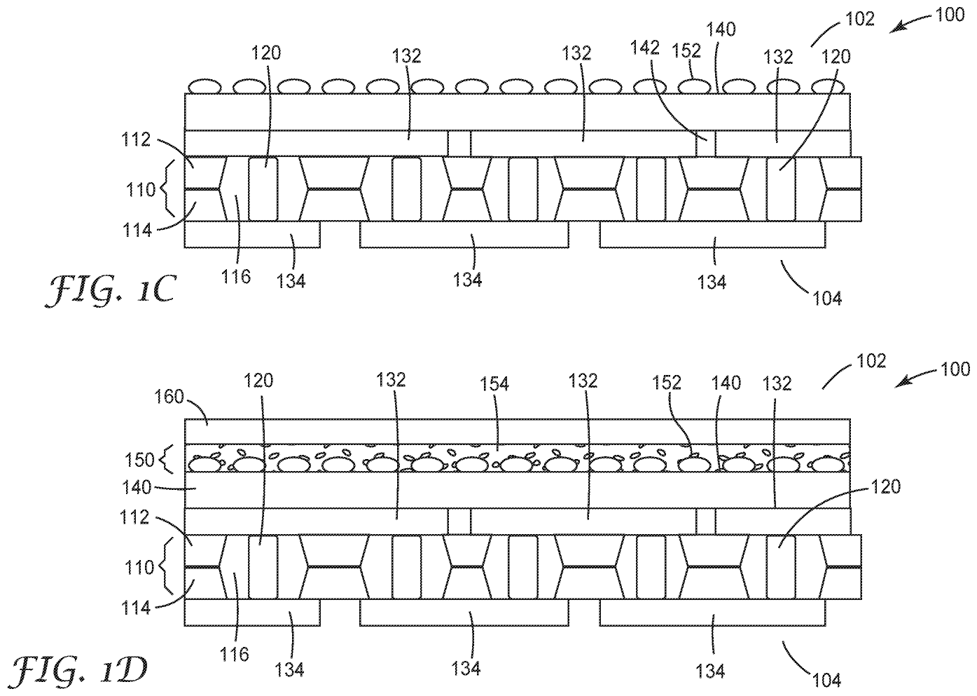

FIGS. 1A-D illustrate a process of forming a flexible thermoelectric device 100, according to some embodiments. The flexible thermoelectric device 100 includes a flexible substrate 110 having a first side 102 and a second side 104 opposite to the first side 102. A plurality of thermoelectric elements 120 are supported by the flexible substrate 110. The plurality of thermoelectric elements 120 are electrically connected by a first set of electrodes 132 on the first side 102 and a second set of electrodes 134 on the second side 104.

In the illustrated embodiment of FIG. 1A, the substrate 110 is formed by laminating a first flexible substrate 112 and a second flexible substrate 114. The first set of electrodes 132 are formed on the first flexible substrate 112. The second set of electrodes 134 are formed on the second flexible substrate 114. The thermoelectric elements 120 are supported by the flexible substrate 110. In the depicted embodiments, vias 116 are formed into the substrate 110 through which the thermoelectric elements 120 can extend and be attached therein. In some embodiments, the vias 116 can be formed by etching the flexible substrate(s).

In some embodiments, the first and second flexible substrates 112 and 114 can be aligned and laminated where vertical or via conductors (e.g., solder) can be used to electrically connect the thermoelectric elements 120 to the respective electrodes 132 and 134. It is to be understood that the substrate 110 may have any suitable configurations to support the thermoelectric elements and the electrodes. The substrate 110 may be a flexible substrate made of any suitable materials such as, for example, polyethylene, polypropylene, cellulose, etc. The electrodes 132 and 134 can include any suitable electrically conductive materials such as, metals, metal alloys, etc.

The thermoelectric elements 120 include one or more p-type thermoelectric elements and one or more n-type thermoelectric elements alternatingly connected in series by the electrodes 132 and 134. In some embodiments, the thermoelectric elements may be formed by disposing (e.g., printing, dispensing, etc.) thermoelectric materials onto the substrate 110. In some embodiments, the thermoelectric elements may be provided in the form of thermoelectric solid chips. The p-type thermoelectric elements may be made of a p-type semiconductor material such as, for example, Sb₂Te₃ or its alloys. The n-type thermoelectric elements may be made of an n-type semiconductor material such as, for example, Bi₂Te₃ or its alloys. The semiconductors can be placed thermally in parallel to each other and electrically in series and then joined with a thermally conducting plate on each side. Exemplary thermoelectric devices and methods of making and using the same are described in U.S. Patent Application No. 62/353,752 (Lee et al.), which is incorporated herein by reference.

The thermoelectric device 100 can work as a cooler or heater based on the so-called Peltier effect. When an electric current flows through the device, it brings heat from one side to the other, so that one side gets cooler while the other gets hotter. In many conventional applications, the hot side 102 is attached to a heat sink (e.g., a ceramic or metal plate) so that it remains at ambient temperature, while the cool side 104 goes below room temperature. Applying a rigid heat sink onto the hot side 102 may sacrifice the flexibility of the thermoelectric device.

As illustrated in the embodiment of FIG. 1B, the thermoelectric device 100 further includes a layer of thermal interface material (TIM) 140 covering the first side 102 of the substrate 110. The thermal interface material 140 may include one or more pressure-sensitive adhesive (PSA) based materials such as, for example, thermally conductive adhesive tape materials commercially available from 3M Company (Saint Paul, Minn., USA). The thermal conductivity of the suitable PSA based material may be in a range, for example, from about 0.25 to about 10 mK/W. The layer 140 may have a thickness, for example, in the range from about 10 to about 300 micrometers. The thermal interface material 140 can be disposed on the hot side 102 to cover the electrodes 132 and has a flexibility to fill in a space 142 therebetween by any suitable processes such as, for example, laminating, coating, drop casting, spreading, printing, etc.

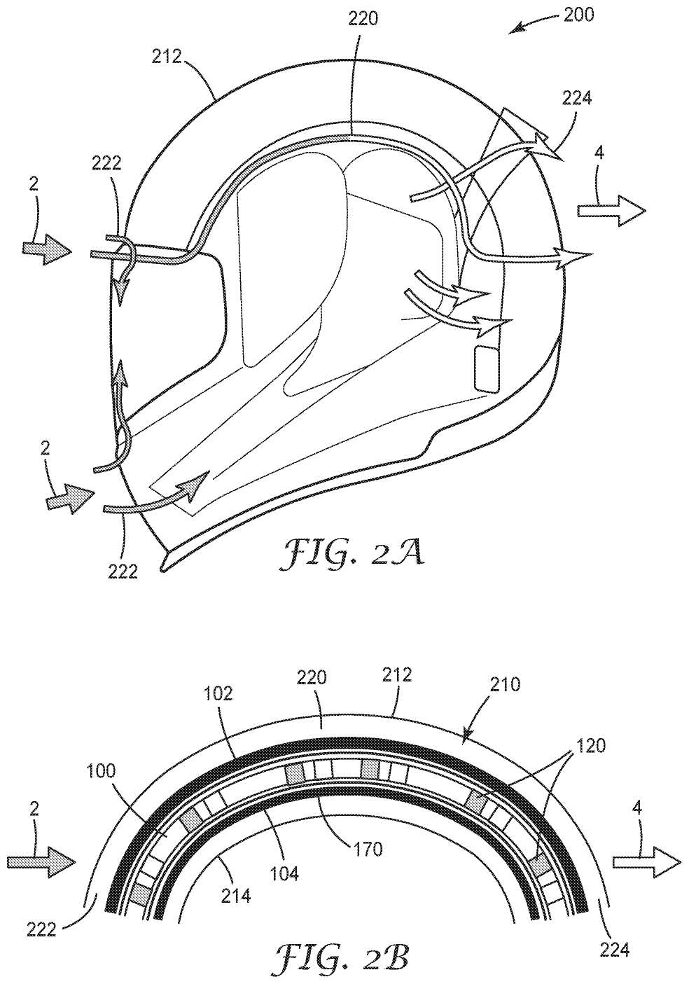

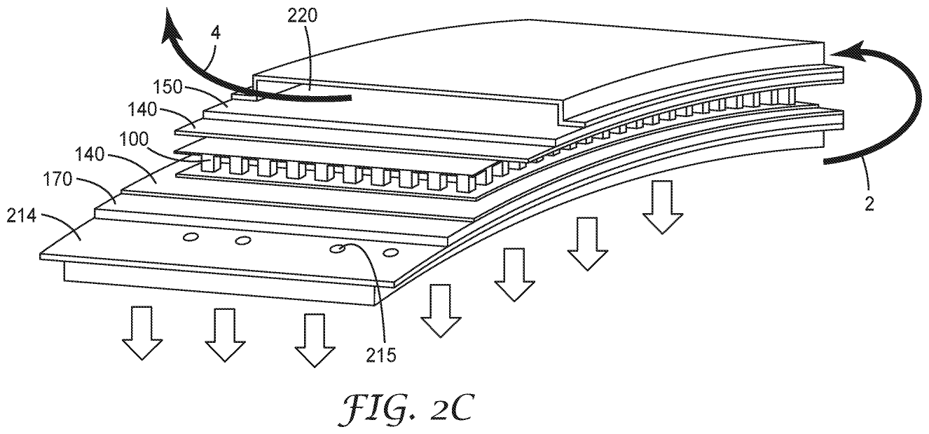

The thermoelectric device 100 further includes one or more water harvesting materials 150 (see FIG. 2D) being disposed on the first side 102 to absorb water or moisture and dissipate heat by evaporation of the absorbed water or moisture. The one or more water harvesting materials 150 include at least one of a superabsorbent polymer (SAP) material and a metal-organic framework (MOF) material. The layer 150 of water harvesting materials may have a thickness in the range, for example, from about 100 micrometers to about 10 mm.

As shown in the embodiment of FIG. 2C, the SAP material 152 is disposed on the TIM 140. The SAP material described herein may intake up to, for example, about 100 wt. % to about 300 wt. % water or even more of its own weight. The SAP may swell by absorbing water, for example, with an increasing volume of about 10% to about 500%. In general, the SAPs used herein as hydrogels, relative to their own mass can absorb and retain extraordinary large amounts of water or aqueous solution. These ultrahigh absorbing materials can imbibe deionized water as high as 10 to 1000 g/g. One exemplary SAP may include polyacrylic acid sodium salt, which is commercially available from Sigma-Aldrich Corporation, St. Louis, Mo. It can present in a powder form, and the particle size can be, for example, less than about 1000 micrometers. It is to be understood that any suitable SAP materials can be used herein, including, for example, polyacrylamide co-polymer, starch-acrylonitrile co-polymer, polyvinyl alcohol, carboxy methyl cellulose, isobutylene maleic anhydride, cross-linked acrylic-acrylamide co-polymers, super absorbent fibers, etc.

When the temperature raises on the hot side 102 of the device 100, water in the SAP material 152 starts to evaporate to cool down the hot side 102. In some embodiments, the SAP material 152 may absorb a suitable amount of coolant which is hydrophilic in nature to promote water absorption. Exemplary coolants may include, for example, glycol, glycerol, etc. The coolants may have a higher binding energy with the SAP material 152 than water, and thus have a slower evaporation rate than water. Adding a suitable amount of coolants into the SAP material 152 can help to adjust the cooling rate/time for the hot side 102 of the device 100. In some embodiments, the SAP material 152 may include, for example, 5 to 40 vol. % of coolant.

In some embodiments, the water harvesting materials 150 may include a porous metal-organic framework (MOF) material. The porous MOF material can be disposed on the TIM 140, mixing with the SAP material. As shown in the embodiment of FIG. 2D, the MOF material 154 is coated on the TIM 140 at the side opposite to the electrodes 132. The MOF tends to adsorb water up to about 50% to about 90% of its own weight. The MOF may swell by absorbing water, with an increasing volume of about 10 vol. % to about 100 vol. %.

Metal organic framework (MOF) materials belong to a crystalline nano-porous material family including thousands of different structures. MOF materials can be self-assemblies of metal ions (e.g., acting as coordination centers) and organic ligands (e.g., acting as linkers between metal centers). MOF materials, as one of the most exciting recent developments in nanoporous material science, have been also termed as coordination polymers, hybrid organic-inorganic materials, metal organic polymers, or porous coordination networks in the literature. The unique combination of high porosity, lack of nonaccessible bulk volume, very large surface areas, wide range of pore sizes and topologies, and infinite number of possible structures can make MOF materials attractive alternatives to the traditional nanoporous materials in many scientific and industrial fields. Water adsorption in porous MOFs and related materials is described in “Water Adsorption in Porous Metal-Organic Frameworks and Related Materials,” J. Am. Chem. Soc., 2014, 136, 4369-4381, which is incorporated herein by reference.

In some embodiments, the MOF materials used herein can provide a good selection of different pore shapes and sizes, different metals (e.g., Al, Cu, Fe, Zn, etc.) and different organic linkers (BDC, BTC, mIM, etc.). One exemplary MOF material may include copper benzene-1,3,5-tricarboxylate Cu-BTC, which is commercially available from Sigma-Aldrich Corporation, St. Louis, Mo., under the tradename Basolite® C300. That exemplary MOF material can present in the form of white powder in nature with a particle size of about 15.96 micrometers. The water adsorption characteristics of the MOF material is about 20 to about 60 wt. % depending on the humidity. It is to be understood that various MOF or MOF-based materials can be used herein, including, for example, ditopic organic carboxylates, polytopic organic carboxylates, porphyrin-based MOFs, MOF-177, MOF-210, postsynthetic modification of MOFs, multivariate MOFs (MTV-MOF), MTV-MOF-5, etc.

When the temperature raises on the hot side 102 of the device 100, water in the MOF 154 can evaporate to dissipate heat from the hot side 102. The MOF materials described herein have a high performance of water capture, which helps to capture water even from low humidity environment. The porous MOF materials can spontaneously pull water out of the surrounding air even at low humidity when their pores are the right size and their interior surfaces are hydrophilic (e.g., negatively charged molecules). In some embodiments, the pore size of the MOF materials can be chosen such that the water adsorbs to the MOF's pores and desorbs therefrom with a modest energy input. Suitable MOF materials may have a desirable surface area, for example, ranging from about 1,000 to about 10,000 m²/g, and a pore aperture, for example, ranging from about 2 nanometers to 10 nanometers. Such adsorption and desorption characteristics can be utilized to maximize its water-absorption/desorption capacity.

In the embodiment depicted in FIG. 1D, the layer 150 of water harvesting materials includes a mixture of the SAP material and the MOF material. The MOF material 154 is attached or coated on the SAP layer 152 such that the MOF material and the SAP material are in direct contact with each other. The mixture can include, for example, about 50 wt % to about 90 wt % of the SAP material, and about 50 wt % to about 10 wt % of the MOF material. In some embodiment, the majority of the water harvesting material 150 can be the SAP material. For example, the ratio of SAP/MOF can be greater than 2:1, 5:1, 10:1, or 20:1. It is to be understood that the ratio can be any suitable values from 50:50 wt. % to 99:1 wt. %, depending the circumstances (e.g., atmosphere humidity). In some embodiments, the powders of SAP and MOF cam be mixed and applied onto the hot side of a thermoelectric device. In some embodiments, the SAP powder can be disposed on the hot side first, and followed by the MOF powder on top of it.

The MOF material can adsorb moisture even at low humidity, then desorb and condense into water with low-grade energy sources (e.g., solar energy). Continuously condensed water can be absorbed by or transported to the proximate SAP material for hot circuit cooling. Such combination can make full use of both SAP and MOF materials considering that (i) the MOF material is capable of adsorbing moisture from the surrounding atmosphere even at low humidity and (ii) the SAP material tends to adsorb and store more water than the MOF material (e.g., from about 100% to about 300% of its own weight vs. from about 50% to about 90% of its own weight). The SAP material can be applied onto the hot side of the thermoelectric device and evaporate to cool down the hot side when the temperature raises, whereas the MOF material can adsorb moisture at room temperature even at very low humidity and automatically refill the SAP layer by condensing water, which eliminates the necessity of using a water pump for pumping water into the SAP layer, and allows to harvest water even at low humidity.

The layer 150 of water harvesting materials is then covered by a porous layer 160, which holds the water harvesting materials 152 and/or 154 onto the hot side 102 of the device. The porous layer 160 can allow moisture to penetrate therethrough to reach the MOF or SAP material. The porous layer 160 also has a compressibility such that it can leave room for the MOF and SAP materials to expand when absorbing water or moisture. In some embodiments, the porous layer 160 can be, for example, a thin layer of flexible non-woven. The porous layer may have a thickness in the range, for example, from about 100 microns to about 5 mm. It is to be understood that the porous layer may include any suitable porous materials including, for example, ultrahigh-molecular-weight polyethylene porous film, adaptive fluid-infused porous film, chemically-etched honeycombs thin film, photo-crosslinked hierarchical porous polymer film, etc.

The flexible thermoelectric device 100 can be flexible enough to conform to or wrap around to an object surface having various shapes, with the cool side 104 in contact to or in proximity with the object surface. The present disclosure provides methods for managing thermal profile or dissipating heat from the hot side of the thermoelectric device 100 without affecting the flexibility of the thermoelectric device.

FIG. 2A illustrates a simplified schematic perspective view of a protective helmet 200 including a thermoelectric cooler 210, according to one embodiment. FIG. 2B illustrates a cross-sectional view of a portion of the protective helmet 200 of FIG. 2A. FIG. 2C illustrates an exploded perspective view of a portion of the protective helmet 200 of FIG. 2A. The protective helmet 200 includes a helmet body including an outer shell 212 and an inner shell 214 attached to an inner surface of the outer shell 212. The outer shell 212 may have a hemispherical shape, and the inner shell 214 may be conformal to the shape of a wearer's head. The inner shell 214 may include an impact absorbing material such as, for example, a foamed resin, to shield the wearer's head from an impact. The thermoelectric cooler 210 is disposed between the outer shell 212 and the inner shell 214 of the helmet body.

The thermoelectric cooler 210 includes the thermoelectric device 100 of FIG. 1D. The thermoelectric device 100 is flexible and positioned to conform to the shape of the outer shell 212 or the inner shell 214 of the helmet body. The hot side 102 of the thermoelectric device 100 is adjacent to the outer shell 212, and the cool side 104 is adjacent to the inner shell 214. The thermoelectric cooler 210 uses the so-called Peltier effect to create a heat flux between the hot side 102 and the cool side 104. For example, when an electrical current run through the thermoelectric elements 120, heat can be transferred from the cool side 104 to the hot side 102 with consumption of the electrical energy. In this manner, the cool side 104 can be maintained at a relatively lower temperature that is comfortable for a wearer of the helmet 200.

A cold plate 170 is disposed on the cool side 104 of the thermoelectric device 100, in proximate to the inner shell 104. A layer of thermal interface material (TIM) 140 can be positioned between the thermoelectric device 100 and the cold plate 170 to enhance the heat exchange therebetween. The cold plate 170 can be made of a flexible thermal-conductive material such as, for example, a metal film (e.g., an aluminum film). In the embodiment depicted in FIG. 2C, the inner shell 214 includes one or more cool channels 215 formed on the cool side of the thermoelectric device 100 to conduct the cool air toward a wearer's head.

The helmet body of the protective helmet 200 further includes one or more air channels 220 formed on the hot side 102 of the thermoelectric device 100. The air channels 220 can be formed between the outer shell 212 of the helmet body and the hot side 102 of the thermoelectric device 100. The air channels 220 include an air inlet 222 at a front side of the helmet body to direct air 2 into the channels 220, and an air outlet 224 at a rear side of the helmet body to direct air 4 out of the channels 220. Air can be conducted, via the air inlet 222, into the air channels 220, to conduct heat exchange with the hot side 102 of the thermoelectric device 100, and exit the air channels 220 via the air outlet 224. As shown in FIG. 2C, the flowing air 2 in the air channel 220 can access to the layer 150 of water harvesting materials through the porous layer 160 (not shown). The water stored in the layer 150 can be effectively evaporated to dissipate heat on the hot side 102 and exit the channel 220 along with the air flow 4.

In some embodiments, the protective helmet 200 can be a motorcyclist helmet. The movement of air during riding can force the convection heat dissipation through the air channels 220. In this manner, the heat collected at the hot side 102 can be quickly exhausted to the ambient by means of the forced air convection.

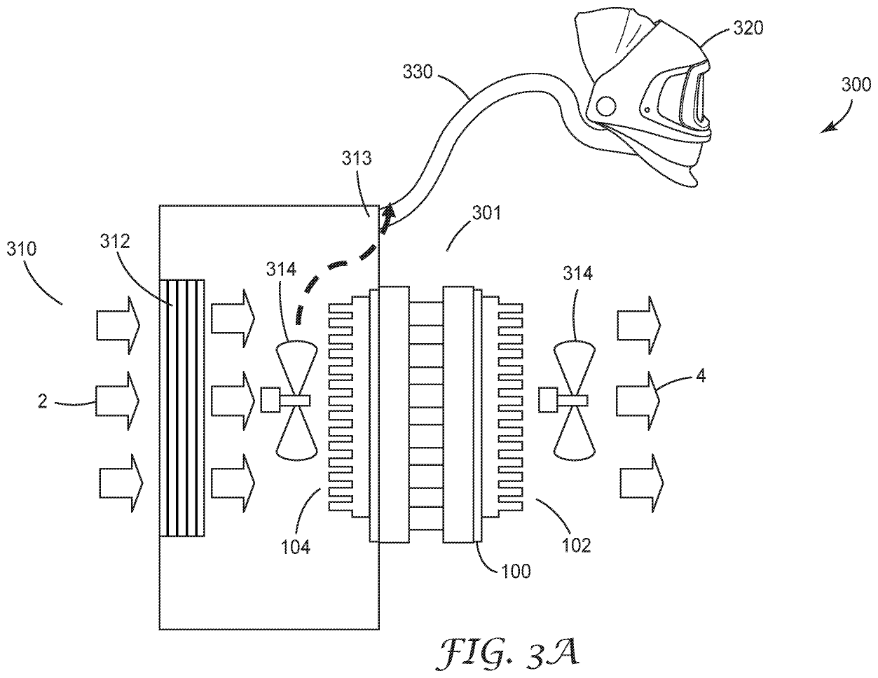

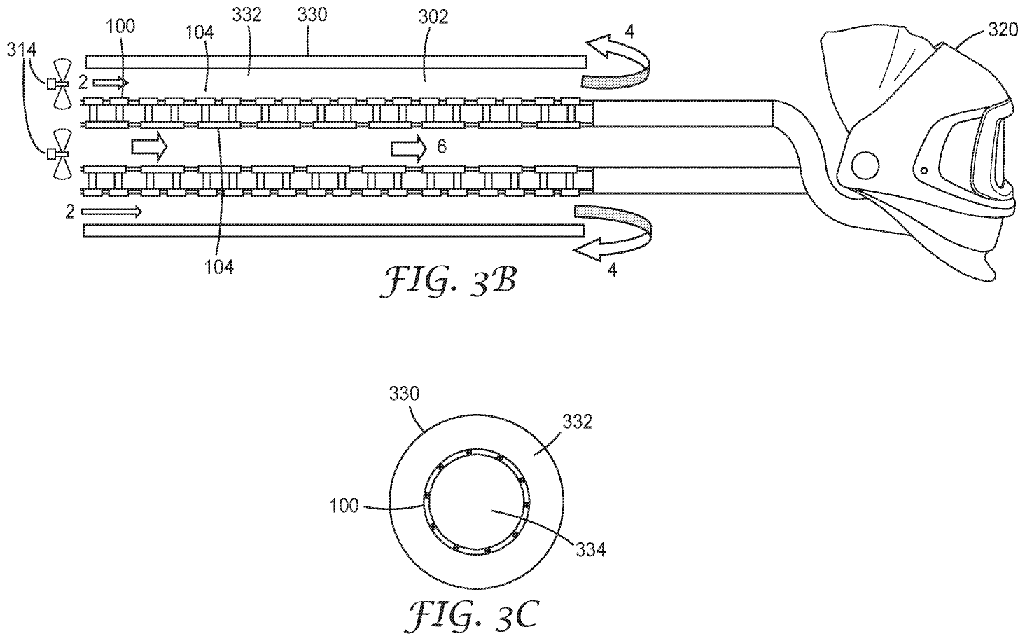

FIG. 3A illustrates a schematic view of an air respirator system 300 including a thermoelectric cooler 301 disposed in an air box, according to one embodiment. The air respirator system 300 includes a head gear 320, an air box 310, and a breathing tube 330 fluidly connected the air outlet 313 to the head gear 320. The air box 310 includes an air inlet 312 to direct air 2 into the air box and an air outlet 313 to direct air into the breathing tube 330. One or more filters can be provided at the air inlet 312. The thermoelectric cooler 301 includes the thermoelectric device 100 of FIG. 1D. The thermoelectric device 100 is flexible and positioned to conform to the shape of the air box 310. The hot side 102 of the thermoelectric device 100 is positioned outside of the air box 310, while the cool side 104 faces the inside of the air box 310.

Air can be conducted into the air box 310 via the air inlet 312, and directed toward the cool side 104 of the thermoelectric cooler 301. The cooled air can be directed out of the air box 310 via the air outlet 313 into the breathing tube 330. One or more fans 314 can be used to direct the air flow.

One or more thermoelectric coolers can be disposed inside the breathing tube 330 to independently or supplementally cool the air to be conducted to the head gear 320. In the embodiment depicted in FIG. 3B, a thermoelectric cooler 302 is disposed inside the breathing tube 330. FIG. 3C illustrates a cross-sectional view of the breathing tube 330 of FIG. 3B. The thermoelectric cooler 302 includes the thermoelectric device 100 of FIG. 1D that is present in the form a thermoelectric air pipe extending inside the breathing tube 330 to deliver airflow to the head gear 320. The hot side 102 of the thermoelectric device 100 forms an outer side of the thermoelectric air pipe; and the cool side of the thermoelectric device 100 forms a cool airflow channel 334 of the thermoelectric air pipe. The air from the air box 310 can be directed into the air channel and further cooled by the cool side 102 of the thermoelectric device 100. An exhaust airflow channel 332 can be formed between the breathing tube 330 and the thermoelectric air pipe 302 to dissipate heat from the hot side 104 of the thermoelectric cooler 302. One or more fans 314 can be provided to enhance the air flow 2 along the exhaust airflow channel 302 to an exit 4, and enhance the air flow 6 along the cool airflow channel 334 into the head gear 320.

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Exemplary embodiments of the present disclosure may take on various modifications and alterations without departing from the spirit and scope of the present disclosure. Accordingly, it is to be understood that the embodiments of the present disclosure are not to be limited to the following described exemplary embodiments, but is to be controlled by the limitations set forth in the claims and any equivalents thereof.

### Listing of Exemplary Embodiments

Exemplary embodiments are listed below. It is to be understood that any one of embodiments 1-22 and 23-26 can be combined.

Embodiment 1 is a thermoelectric device comprising:

a flexible substrate having opposite first and second sides;

a plurality of thermoelectric elements supported by the flexible substrate, the plurality of thermoelectric elements being electrically connected by a first set of electrodes on the first side and a second set of electrodes on the second side; and one or more water harvesting materials being disposed on the first side, configured to absorb water or moisture and dissipate heat by evaporation of the absorbed water or moisture.

Embodiment 2 is the thermoelectric device of embodiment 1, wherein the one or more water harvesting materials include at least one of a superabsorbent polymer (SAP) material and a metal-organic framework (MOF) material.

Embodiment 3 is the thermoelectric device of embodiment 1 or 2, further comprising a layer of thermal interface material (TIM) covering the first side of the substrate, and the one or more water harvesting materials being disposed on the layer of TIM on the side opposite to the first set of electrodes.

Embodiment 4 is the thermoelectric device of embodiment 2 or 3, wherein the superabsorbent polymer (SAP) material is capable of absorbing water from about 100% to about 300% of its own weight.

Embodiment 5 is the thermoelectric device of embodiment 2 or 3, wherein the metal-organic framework (MOF) includes self-assemblies of metal ions and organic ligands as linkers between the metal ions.

Embodiment 6 is the thermoelectric device of any one of embodiments 2-5, wherein the water harvesting materials include a mixture of the superabsorbent polymer (SAP) material and the metal-organic framework (MOF) material, and the superabsorbent polymer (SAP) material is positioned to absorb water from the proximate MOF material.

Embodiment 7 is the thermoelectric device of embodiment 6, wherein the mixture comprises about 50.0 wt % to about 99.0 wt % of the SAP material.

Embodiment 8 is the thermoelectric device of embodiment 6 or 7, wherein the mixture comprises about 50.0 wt % to about 1.0 wt % of the MOF material.

Embodiment 9 is the thermoelectric device of any one of embodiments 1-8, further comprising a porous layer to cover the water harvesting materials.

Embodiment 10 is the thermoelectric device of any one of embodiments 1-9, wherein the flexible substrate includes a first flexible circuit and a second circuit laminated with each other.

Embodiment 11 is a thermoelectric cooler (TEC) of any preceding embodiments, further comprising a flexible metal film disposed on the second side as a cold plate.

Embodiment 12 is the thermoelectric cooler of embodiment 11, further comprising a layer of thermal interface material (TIM) between the second side of the substrate and the cold plate.

Embodiment 13 is a protective helmet comprising:

a helmet body including an outer shell and an inner shell; and
the thermoelectric cooler of embodiment 11 disposed between the outer shell and the inner shell of the helmet body, the cold plate being adjacent to the inner shell.

Embodiment 14 is the protective helmet of embodiment 13, wherein the helmet body includes one or more air channels formed on the first side of the thermoelectric device.

Embodiment 15 is the protective helmet of embodiment 14, wherein the air channels include an air inlet at a front side of the helmet body and an air outlet at a rear side of the helmet body.

Embodiment 16 is the protective helmet of any one of embodiments 13-15, wherein the helmet body includes one or more cool air channels formed on the second side of the thermoelectric device.

Embodiment 17 is an air respirator system comprising:

a head gear;

an air box including an air inlet and an air outlet;

a breathing tube fluidly connected the air outlet of the air box to the head gear; and

the thermoelectric device of any one of embodiments 1-10 positioned to cool an air flow into the head gear.

Embodiment 18 is the air respirator system of embodiment 17, wherein the first side of the thermoelectric device faces the inside of the air box, and the other side is outside the air box.

Embodiment 19 is the air respirator system of embodiment 17 or 18, wherein the thermoelectric device is disposed inside the breathing tube in the form of a thermoelectric air pipe extending inside the breathing tube to deliver airflow to the head gear.

Embodiment 20 is the air respirator system of embodiment 19, wherein an exhaust airflow channel is formed between the breathing tube and the thermoelectric air pipe.

Embodiment 21 is the air respirator system of any one of embodiments 17-20, further comprising a filter disposed at the air inlet of the air box.

Embodiment 22 is the air respirator system of any one of embodiments 17-21, further comprising a fan disposed inside the air box to direct air flow towards the air outlet.

Embodiment 23 is a method of making a thermoelectric device comprising:

providing a flexible substrate having opposite first and second sides;

providing a plurality of thermoelectric elements supported by the flexible substrate, the plurality of thermoelectric elements being electrically connected by a first set of electrodes on the first side and a second set of electrodes on the second side; and disposing one or more water harvesting materials on the first side configured to absorb water or moisture and dissipate heat by evaporation of the absorbed water or moisture.

Embodiment 24 is the method of embodiment 23 further comprising covering the first side of the substrate with a layer of thermal interface material (TIM), the one or more water harvesting materials being disposed on the layer of TIM on the side opposite to the first set of electrodes.

Embodiment 25 is the method of embodiment 23 or 24 further comprising laminating a first flexible circuit and a second flexible circuit to form the flexible substrate.

Embodiment 26 is the method of any one of embodiments 23-25 further comprising disposing a flexible metal film on the second side as a cold plate.

Reference throughout this specification to “one embodiment,” “certain embodiments,” “one or more embodiments,” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment,” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, various exemplary embodiments have been described. These and other embodiments are within the scope of the following claims.

1. A thermoelectric device comprising:
a flexible substrate having opposite first and second sides;
a plurality of thermoelectric elements supported by the flexible substrate, the plurality of thermoelectric elements being electrically connected by a first set of electrodes on the first side and a second set of electrodes on the second side; and
one or more water harvesting materials being disposed on the first side, configured to absorb water or moisture and dissipate heat by evaporation of the absorbed water or moisture.

2. The thermoelectric device of claim 1, wherein the one or more water harvesting materials include at least one of a superabsorbent polymer (SAP) material and a metal-organic framework (MOF) material.

3. The thermoelectric device of claim 1, further comprising a layer of thermal interface material (TIM) covering the first side of the substrate, and the one or more water harvesting materials being disposed on the layer of TIM on the side opposite to the first set of electrodes.

4. The thermoelectric device of claim 2, wherein the superabsorbent polymer (SAP) material is capable of absorbing water from about 100% to about 300% of its own weight.

5. The thermoelectric device of claim 2, wherein the metal-organic framework (MOF) material includes self-assemblies of metal ions and organic ligands as linkers between the metal ions.

6. The thermoelectric device of claim 2, wherein the water harvesting materials include a mixture of the superabsorbent polymer (SAP) material and the metal-organic framework (MOF) material, and the superabsorbent polymer (SAP) material is positioned to absorb water from the proximate MOF material.

7-8. (canceled)

9. The thermoelectric device of claim 1, further comprising a porous layer to cover the water harvesting materials.

10. The thermoelectric device of claim 1, wherein the flexible substrate includes a first flexible circuit and a second circuit laminated with each other.

11-12. (canceled)

13. A protective helmet comprising:
a helmet body including an outer shell and an inner shell; and
the thermoelectric device of claim 1 disposed between the outer shell and the inner shell of the helmet body, and a flexible metal film disposed as a cold plate adjacent to the inner shell.

14. The protective helmet of claim 13, wherein the helmet body includes one or more air channels formed on the first side of the thermoelectric device.

15. The protective helmet of claim 14, wherein the air channels include an air inlet at a front side of the helmet body and an air outlet at a rear side of the helmet body.

16. The protective helmet of claim 13, wherein the helmet body includes one or more cool air channels formed on the second side of the thermoelectric device.

17. An air respirator system comprising:
a head gear;
an air box including an air inlet and an air outlet;
a breathing tube fluidly connected the air outlet of the air box to the head gear; and
the thermoelectric device of claim 1 positioned to cool an air flow into the head gear.

18. The air respirator system of claim 17, wherein the first side of the thermoelectric device faces the inside of the air box, and the other side is outside the air box.

19. The air respirator system of claim 17, wherein the thermoelectric device is disposed inside the breathing tube in the form of a thermoelectric air pipe extending inside the breathing tube to deliver airflow to the head gear.

20. The air respirator system of claim 19, wherein an exhaust airflow channel is formed between the breathing tube and the thermoelectric air pipe.

21-22. (canceled)

23. A method of making a thermoelectric device comprising:
providing a flexible substrate having opposite first and second sides;
providing a plurality of thermoelectric elements supported by the flexible substrate, the plurality of thermoelectric elements being electrically connected by a first set of electrodes on the first side and a second set of electrodes on the second side; and
disposing one or more water harvesting materials on the first side configured to absorb water or moisture and dissipate heat by evaporation of the absorbed water or moisture.

24. The method of claim 23 further comprising covering the first side of the substrate with a layer of thermal interface material (TIM), the one or more water harvesting materials being disposed on the layer of TIM on the side opposite to the first set of electrodes.

25. The method of claim 23 further comprising laminating a first flexible circuit and a second flexible circuit to form the flexible substrate.

26. The method of claim 23 further comprising disposing a flexible metal film on the second side as a cold plate.
